(19) United States
(12) Patent Application Publication
(10) Pub. No.: US 2004/0229420 A1
(43) Pub. Date: Nov. 18, 2004

(54) Method for manufacturing semiconductor device having trench gate

(75) Inventor: Takumi Shibata, Kariya-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/834,029

(22) Filed: Apr. 29, 2004

(30) Foreign Application Priority Data
May 14, 2003 (JP) 2003-135543
Jan. 28, 2004 (JP) 2004-20266

(51) Int. Cl. H01L 21/336

(52) U.S. Cl. 438/202

(57) ABSTRACT

A method for manufacturing a semiconductor device having a trench gate is provided. The method includes the steps of: forming a trench in a substrate, the trench having a depth equal to or deeper than 10 μm; annealing the substrate in a reducing atmosphere; and forming a gate insulation film on an inner wall of the trench. The substrate is annealed at a temperature between 950° C. and 1030° C. under a pressure of the reducing atmosphere equal to or higher than 20 kPa in the step of annealing. The semiconductor device includes a transistor having excellent properties. Specifically, a threshold voltage of the transistor is substantially uniformed, a gate oxide film of the transistor is not deteriorated, and crystal defects near the trench are reduced.

### CROSS REFERENCE TO RELATED APPLICATIONS

This application is based on Japanese Patent Applications No. 2003-135543 filed on May 14, 2003, and No. 2004-20266 filed on Jan. 28, 2004, the disclosures of which are incorporated herein by reference.

### FIELD OF THE INVENTION

The present invention relates to a method for manufacturing a semiconductor device having a trench gate.

### BACKGROUND OF THE INVENTION

A trench gate type semiconductor device such as a trench gate type MOS (i.e., metal-oxide semiconductor) transistor and a trench gate type IGBT (i.e., insulated gate bipolar transistor) has a gate electrode in a trench. This device is manufactured as follows. After a trench is formed in a silicon substrate, a gate insulation film is formed on an inner wall of the trench. Then, a conductive material as the gate electrode is embedded in the trench through the gate insulation film so that the trench gate is formed.

For example, a MOS transistor is disclosed in Japanese Patent No. 3356162 (i.e., U.S. Pat. No. 6,525,375). The MOS transistor has a deep trench gate to reduce an ON-state resistance. For example, when the transistor has the trench gate having a depth of 30 μm, it is possible to reduce the ON-state resistance under a theoretical limitation in a conventional MOS transistor. To form the trench having the depth of 30 μm, it is required that density of plasma in a dry-etching process becomes higher and etching time becomes longer compared with a trench etching process condition of the conventional MOS transistor. In this case, the substrate may be damaged during the trench etching process, so that crystal defects may be formed inside of the substrate near the trench.

In general, when the trench gate is formed, in a case where an anisotropic etching method such as a dry etching method is used to form the trench, the crystal defects may be formed in the sidewall of the trench and/or inside of the substrate near the trench. The crystal defects may cause a current leakage at a PN junction and a deterioration of a gate oxide film. To reduce the crystal defects formed by the anisotropic etching, the substrate is processed by a CDE (i.e., chemical dry etching) method or a wet etching method using a hydrofluoric nitric acid after the trench is formed.

Further, to improve characteristics of the trench gate such as a gate withstand voltage, not only a recovery of the crystal defects near the trench but also a smoothing of the sidewall of the trench and an improvement of shapes of an opening and a bottom of the trench are necessitated. Therefore, a method for promoting a migration of silicon atoms disposed on the surface of the substrate is disclosed in Japanese Patent Application Publication No. 2002-231945 (i.e., U.S. Pat. No. 6,630,389). This method provides to perform a heat treatment at a high temperature in a reducing atmosphere such a hydrogen gas atmosphere to promote the migration after the trench is formed.

FIG. 8 shows a relationship between a height of a convexity and a concavity (i.e., a surface roughness Ra) on the sidewall of the trench and annealing temperature in a hydrogen gas. Silicon atoms become movable (i.e., becomes fluctuating) when the substrate is annealed in the hydrogen gas. Thus, the silicon atoms are rearranged so that the convexity and the concavity having a few nano-meters height from the silicon surface are flattened. This rearrangement of the silicon atoms is known as a migration effect. In general, as shown in FIG. 8, the migration effect of the silicon atoms depends on the annealing temperature in the hydrogen gas. When the substrate is annealed at a temperature equal to or higher than 950° C. in the hydrogen gas, the convexity and the concavity on the sidewall of the trench are sufficiently flattened so that the height of the convexity and the concavity are equal to or lower than 1 nm.

Although the effect for improving the characteristics of the trench such as the smoothing of the sidewall of the trench or the rounding of a corner of the trench is sufficiently obtained by annealing the substrate at 950° C., it is required for recovering the crystal defects to anneal the substrate at a high temperature such as 1150° C. When the substrate is annealed at 1150° C. in the manufacturing process of the semiconductor device (i.e., a transistor), the threshold voltage of the transistor deviates largely from a predetermined design voltage. This deviation is caused by, for example, deviation of the concentration of the channel layer. Specifically, the impurity contained (i.e., doped) in a high concentration impurity layer (i.e., a heavily doped impurity layer) such as a drain layer or a source layer in the semiconductor device is diffused from the substrate to the outside, so that the impurity adheres to the channel layer. Thus, the concentration of the channel layer is changed. Here, the concentration of the impurity in the high concentration impurity layer is equal to or higher than 1×10¹⁹ cm⁻³. Therefore, the high temperature annealing for reducing the crystal defects cause the deviation of the threshold voltage caused by diffusing the impurity outward. Thus, when the substrate is annealed at a high temperature such as 1150° C. in the reducing atmosphere, the surface roughness on the sidewall of the trench is reduced, and the crystal defects are recovered. However, the deviation of the threshold voltage is not improved sufficiently.

### SUMMARY OF THE INVENTION

In view of the above-described problem, it is an object of the present invention to provide a method for manufacturing a semiconductor device including a transistor having excellent properties. Specifically, a threshold voltage of the transistor is substantially uniformed, a gate oxide film of the transistor is not deteriorated, and crystal defects near the trench are reduced.

A method for manufacturing a semiconductor device having a trench gate is provided. The method includes the steps of: forming a trench in a substrate, the trench having a depth equal to or deeper than 10 μm; annealing the substrate in a reducing atmosphere; and forming a gate insulation film on an inner wall of the trench. The substrate is annealed at a temperature between 950° C. and 1030° C. under a pressure of the reducing atmosphere equal to or higher than 20 kPa in the step of annealing. The semiconductor device includes a transistor having excellent properties. Specifically, a threshold voltage of the transistor is substantially uniformed, a gate oxide film of the transistor is not deteriorated, and crystal defects near the trench are reduced.

Preferably, the substrate is annealed at a temperature between 950° C. and 1030° C. under a pressure equal to or higher than 30 kPa in the step of annealing. In this case, the density of the crystal defects in the substrate is reduced lower than 10⁷ cm⁻², which is almost equal to or less than that of a trench gate device manufactured by a conventional method having no annealing process in hydrogen gas.

Preferably, the reducing atmosphere is a hydrogen gas atmosphere. In this case, a migration effect is effectively obtained in the step of annealing.

Preferably, the gate insulation film is an oxide film formed by a CVD (i.e., chemical vapor deposition) method. If a thermal oxidation film is used as the gate insulation film, it is necessitated to deform a shape of a corner of the trench largely for enhancing the migration effect so that the film thickness near the corner of the trench is uniformed. However, in a case where the gate insulation film is the oxide film formed by the CVD method, the film thickness of the gate insulation film is uniformed without deforming the shape of the corner of the trench. Specifically, the film thickness of the gate insulation film is uniformed whether the corner of the trench has a rounding shape. Therefore, the crystal defects near the trench are reduced even if the migration effect is small.

Preferably, the gate insulation film includes an oxide film formed by a CVD method, a nitride film and an oxide film formed by a thermal oxidation method, which are stacked in this order. In this case, the ONO film works as a gate insulation film, and has excellent dielectric constant.

Further, a method for manufacturing a semiconductor device having a trench gate is provided. The method includes the steps of preparing a semiconductor substrate having a first surface and a second surface opposite to the first surface. The substrate includes a source region having a first conductive type, a channel region having a second conductive type, a drift region, and a drain region having the first conductive type. The drain region extends in a vertical direction of the first surface, and is disposed on the first surface of the substrate. The drift region is disposed in the drain region, and extends in the vertical direction of the first surface of the substrate. The channel region is disposed in the drift region, and extends in the vertical direction of the first surface of the substrate. The source region is disposed in the channel region, and extends in the vertical direction of the first surface of the substrate. The method further includes the steps of; forming a trench having a depth equal to or deeper than 10 μm, the trench penetrating the channel region from the source region to reach the drift region in one of directions parallel to the first surface of the substrate; annealing the substrate in a reducing atmosphere; forming a gate insulation film on an inner wall of the trench; and forming a gate electrode in the trench through the gate insulation film. The substrate is annealed at a temperature between 950° C. and 1030° C. under a pressure of the reducing atmosphere equal to or higher than 20 kPa in the step of annealing.

The semiconductor device includes a transistor having excellent properties. Specifically, a threshold voltage of the transistor is substantially uniformed, a gate oxide film of the transistor is not deteriorated, and crystal defects near the trench are reduced.

### BRIEF DESCRIPTION OF THE DRAWINGS

The above and other objects, features and advantages of the present invention will become more apparent from the following detailed description made with reference to the accompanying drawings. In the drawings:

FIGS. 1A-1E are schematic cross sectional views explaining a method for manufacturing a vertical type MOSFET, according to a first embodiment of the present invention;

FIG. 2 is a graph showing a relationship between density of crystal defects and temperature of the annealing process;

FIG. 3 is a graph showing a relationship between threshold voltage and temperature of the annealing process

FIG. 4 is a graph showing a relationship between density of crystal defects and depth of a trench gate;

FIG. 5 is a graph showing a relationship between density of crystal defects and partial pressure;

FIG. 6 is a partially enlarged perspective view showing a substrate near a trench, according to a second embodiment of the present invention;

FIG. 7 is a cross sectional view showing the substrate taken along line VII-VII in FIG. 6; and

FIG. 8 is a graph showing a relationship between a surface roughness Ra of an inner wall of the trench and temperature of an annealing process.

### DETAILED DESCRIPTION OF THE PREFERRED EMBODIMENTS

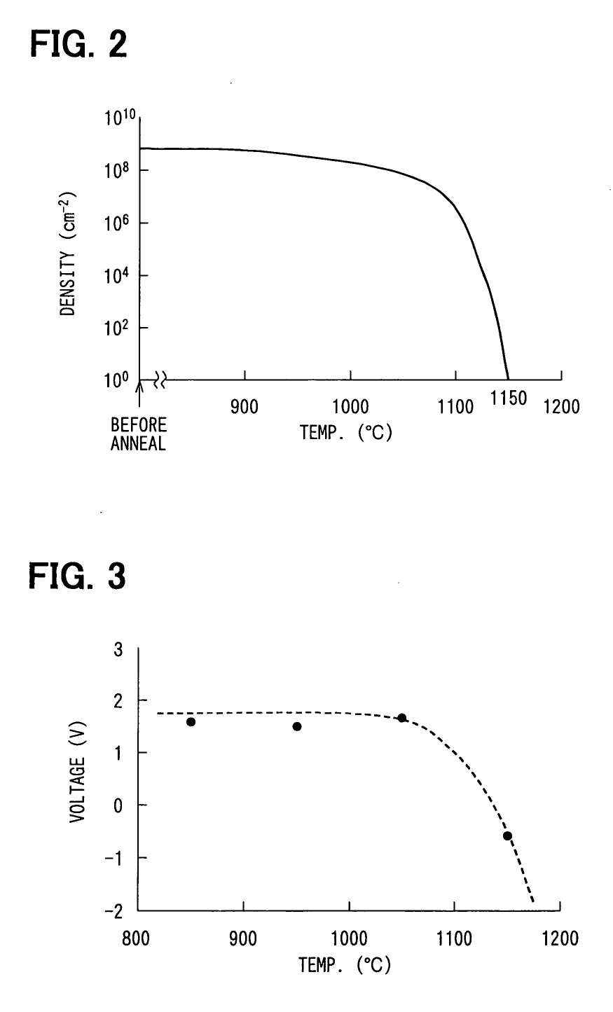

The inventor has preliminarily studied as follows. A semiconductor device is annealed in a reducing atmosphere such as a hydrogen gas to recover (i.e., to reduce) crystal defects in a substrate. FIG. 2 shows a relationship between density of the crystal defects and an annealing temperature in the hydrogen gas. The crystal defects are recovered by annealing the substrate at a high temperature such as 1150° C., as shown in FIG. 2.

FIG. 3 shows a relationship between a threshold voltage of the semiconductor device (i.e., a transistor) and the annealing temperature in the hydrogen gas. When the substrate is annealed at 1150° C. in the manufacturing process of the semiconductor device, the threshold voltage of the transistor deviates largely from a predetermined design voltage. This deviation is caused by, for example, deviation of the concentration of the channel layer. Specifically, the impurity contained (i.e., doped) in a high concentration impurity layer (i.e., a heavily doped impurity layer) such as a drain layer or a source layer in the semiconductor device is diffused from the substrate to the outside, so that the impurity adheres to the channel layer. Thus, the concentration of the channel layer is changed. Here, the concentration of the impurity in the high concentration impurity layer is equal to or higher than 1×10¹⁹ cm⁻³. Therefore, the high temperature annealing for reducing the crystal defects cause the deviation of the threshold voltage caused by diffusing the impurity outward.

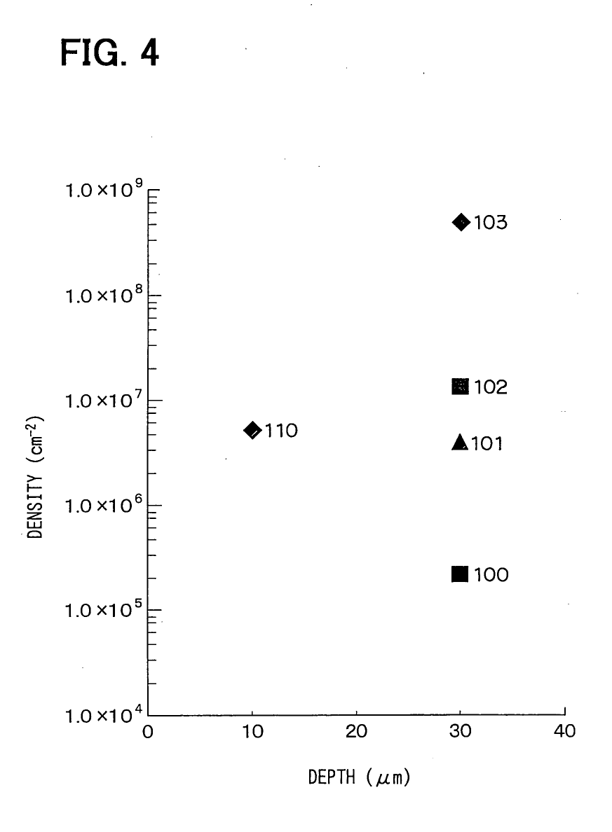

Further, the inventor has studied about a relationship between density of the crystal defects near a trench and a pressure of a reducing atmosphere in an annealing process. The annealing process is performed after the trench is formed in a semiconductor layer. FIG. 4 shows a relationship between the density of the crystal defects and a depth of a trench gate. In FIG. 4, 110 represents a conventional semiconductor device having a trench gate, a depth of which is 10 μm. 100-103 represent semiconductor devices having a trench gate, a depth of which is 30 μm. The semiconductor device 103 is manufactured in a method without annealing in the hydrogen gas. The semiconductor devices 100-102 are manufactured in a method having an annealing process in the hydrogen gas. Specifically, the semiconductor device 102 is manufactured in a method with annealing in the hydrogen gas, a partial pressure of which is 10 kPa. The semiconductor device 101 is manufactured in a method with annealing in the hydrogen gas, a partial pressure of which is 20 kPa. The semiconductor device 100 is manufactured in a method with annealing in the hydrogen gas, a partial pressure of which is 40 kPa.

As shown in FIG. 4, in a case where the device 103 having the trench gate with the depth of 30 μm is not annealed in the hydrogen gas, the density of the crystal defects in the device 103 is higher than that in the device 110 having the trench gate with the depth of 10 μm. As the partial pressure of the hydrogen gas in the annealing process becomes higher, the density of the crystal defects is improved, i.e., reduced. Specifically, when the partial pressure of the hydrogen gas is equal to or higher than 20 kPa, the density of the crystal defects is reduced lower than that of the device 110. As shown in FIG. 2, the density of the crystal defects is almost constant when the annealing temperature in the annealing process is in a range between 950° C. and 1030° C. Therefore, when the annealing temperature in the annealing process is in a range between 950° C. and 1030° C., the impurity in the substrate is not diffused outwardly. Further, the migration effect of the silicon atoms is sufficiently obtained for smoothing the inner wall of the trench so that the oxide film is formed with high quality on the inner wall of the trench. Specifically, when the device is annealed in the hydrogen gas with the partial pressure equal to or lower than 100 Torr (i.e., about 13 kPa), the density of crystal defects in the device is not reduced substantially. However, when the device is annealed in the hydrogen gas with the partial pressure equal to or higher than 20 kPa (i.e., about 150 Torr), the density of crystal defects in the device is reduced without diffusing the impurity outwardly. Here, 1 Torr is 133.322 Pa. Preferably, when the device is annealed in the hydrogen gas with the partial pressure equal to or higher than 40 kPa, the density of the crystal defects in the device is remarkably reduced, so that the density of the crystal defects in the device is lower than 1×10⁶ cm⁻², as shown in FIG. 4.

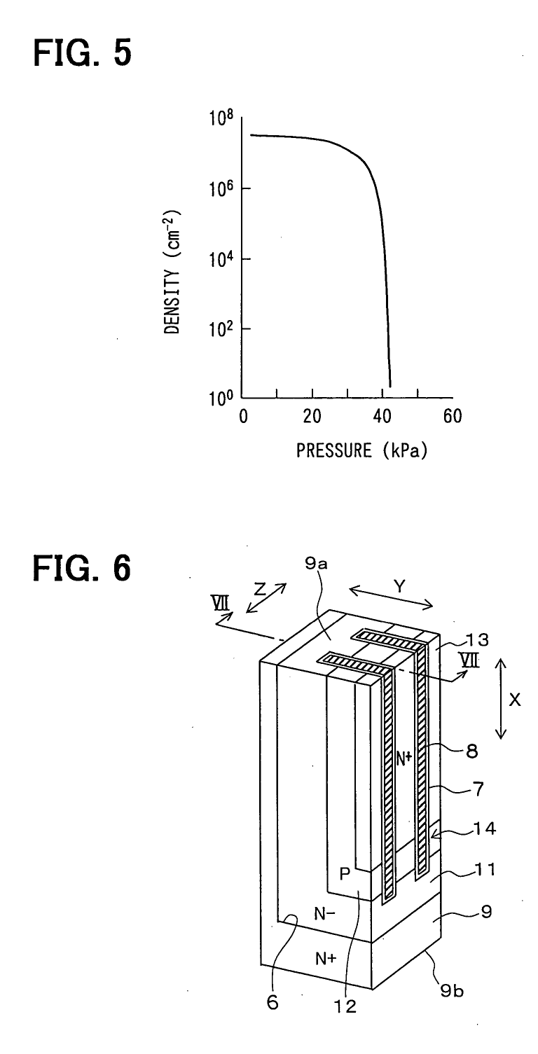

FIG. 5 shows a relationship between the density of the crystal defects and the partial pressure of the hydrogen gas in the annealing process. The density of the crystal defects is slightly reduced when the device is annealed in the hydrogen gas with the partial pressure equal to or higher than 20 kPa. Further, the density of crystal defects is remarkably reduced when the device is annealed in the hydrogen gas with the partial pressure equal to or higher than 40 kPa.

(First Embodiment)

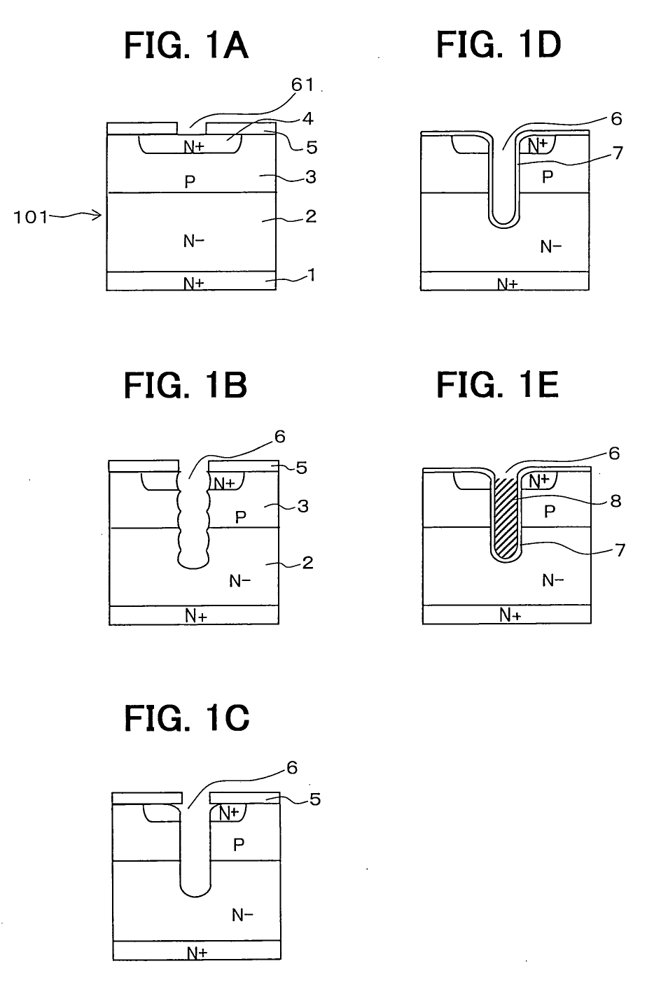

A method for manufacturing a semiconductor device having a trench gate according to a first embodiment of the present invention is shown in FIGS. 1A-1E. FIG. 1A shows a trench mask forming process, which provides to form a mask 5 for a trench 6. Specifically, a N⁻ type layer 2 is formed on a N⁺ type semiconductor substrate 101 by using an epitaxial crystal growth method and the like. Then, a P type channel layer 3 is formed on a foreside surface of the substrate 101 by using an ion implantation method and the like so that the P type impurity is doped from the foreside surface of the substrate 101. Then, a N type source layer 4 is formed on the foreside surface of the substrate 101 by using an ion implantation method and the like so that the N type impurity is doped from the surface of the P type channel layer 3. Thus, the substrate 101 includes the N⁺ type drain layer 1, the N⁻ type layer 2, the P type channel layer 3, and the N type source layer 4. Then, an oxide film as a trench mask 5 is formed on the foreside surface of the substrate 101 (i.e., a principal plane of the substrate 101). Then, an opening of the trench mask 5 is formed on the trench mask 5, which is disposed on a trench-to-be-formed region 61. The trench-to-be-formed region 61 is prepared such that the trench 6 is disposed in the N⁺ source layer 4.

FIG. 1B is a trench etching process. The trench 6 is formed by a dry-etching method. Specifically, the trench 6 penetrates the P type channel layer 3 through the opening of the mask 5, and reaches the N⁻ type layer 2. In a case where an aspect ratio of the trench 6 is high (i.e., the trench 6 is deep), after a part of the trench 6 is formed temporary, the sidewall of the part of the trench 6 is covered with a protection film such as an oxide film protected from etching. Then, the rest of the trench 6 is etched by the dry-etching method so that the bottom of the part of the trench is etched deeply. Then, another part of the trench 6 is formed, and then the sidewall of the other part of the trench 6 is covered again with the protection film. Thus, the dry-etching process and the protection film forming process are repeated alternately. Thus, the trench 6 has a predetermined depth. After that, the protection film is removed from the sidewall of the trench 6, so that the trench 6 has the high aspect ratio.

FIG. 1C is an annealing process in a hydrogen gas. The substrate 101 is annealed in a hydrogen atmosphere. For example, the hydrogen gas has a partial pressure of 20 kPa, and the substrate 101 is annealed at 950° C. during 300 seconds. By the annealing process, a convexity and a concavity formed on an inner wall of the trench 6 are flattened. Further, crystal defects near the trench 6 are also recovered.

FIG. 1D is a gate insulation film forming process. The trench mask 5 is removed, and a gate insulation film (i.e., a gate oxide film) 7 is formed on the inner wall of the trench 6.

FIG. 1E is a gate electrode forming process. A conductive material such as a poly silicon film is embedded in the trench 6 through the gate oxide film 7. Then, the poly silicon film is patterned so that a gate electrode 8 is formed.

Thus, a power MOSFET (i.e., metal-oxide semiconductor field effect transistor) having the gate electrode 8 in the trench 6 is completed.

In the above annealing process in the hydrogen gas, the substrate 101 is annealed in the hydrogen gas having the partial pressure of 20 kPa at a temperature between 950° C. and 1050° C. By the hydrogen annealing process, the crystal defects near the trench 6 are recovered without diffusing the impurity in the substrate 101 outwardly. Thus, the power MOSFET has a high withstand voltage of the gate oxide film 7, and a current leakage in the power MOSFET is prevented. Here, the withstand voltage of the gate oxide film 7 is a breakdown voltage of the gate oxide film 7.

In U.S. Pat. No. 6,630,389, a device is annealed at a temperature between 900° C. and 1000° C. under a pressure about 13 kPa (i.e., 100 Torr). In this annealing process, the partial pressure is much lower than 20 kPa, so that the crystal defects near the trench 6 are not recovered, although the shape of the trench 6 is suitable for forming the gate oxide film 7. Therefore, a junction current at a P-N junction near the trench 6 may be leaked. On the other hand, in this embodiment, the partial pressure is set to be equal to or higher than 20 kPa, so that the crystal defects near the trench 6 are recovered without diffusing the impurity in the substrate 101 outwardly and the shape of the trench 6 is suitable for forming the gate oxide film 7 (i.e., suitable for embedding the conductive material in the trench 6).

(Second Embodiment)

A trench gate type power MOSFET according to a second embodiment of the present invention is shown in FIG. 6. The power MOSFET includes a N⁺ type substrate 9 having a principal plane 9a and a backside surface 9b opposite to the principal plane 9a. A direction of X (i.e., a direction X) corresponds to a thickness direction of the N⁺ type substrate 9. Directions of Y and Z (i.e., directions Y and Z) correspond to horizontal directions of the principal plane 9a of the N⁺ type substrate 9. Here, the principal plane 9a is parallel to the backside surface 9b, and the directions Y and Z are parallel to the principal plane 9a. Further, the directions X, Y and Z are perpendicular to each other.

The trench 6 has a predetermined depth from the principal plane 9a of the N⁺ substrate 9. A N⁻ type drift layer 11 is embedded in the trench 6. Further, a P type channel region (i.e., a P type well region) 12 is formed in a predetermined region of the N⁻ type drift layer 11. The P type channel region 12 has a predetermined depth from the principal plane 9a of the substrate 9. The depth of the P type channel region 12 is, for example, equal to or deeper than 15 μm. However, the depth of the P type channel region 12 is a little bit shallower than that of the N⁻ type drift layer 11.

In the P type channel region 12, a N⁺ type source region 13 is formed in a predetermined region of the P type channel region 12. The N⁺ type source region 13 has a predetermined depth from the principal plane 9a of the substrate 9. The depth of the N type source region 13 is shallower than that of the P type channel region 12. Specifically, a P-N junction between the N⁺ type source region 13 and the P type channel region 12 is shallower than the bottom of the P type channel region 12. The depth of the N⁺ type source region 13 is, for example, equal to or deeper than 15 μm. However, the depth of the N⁺ type source region 13 is a little bit shallower than that of the P type channel region 12.

Further, another trench 14 is formed in the substrate 9. The other trench 14 is disposed from the principal plane 9a of the substrate 9, and is parallel to the direction X (i.e., is perpendicular to the principal plane 9a). The trench 14 penetrates through the P type channel region 12 from the N⁺ type source region 13 in the directions X and Y, which are parallel to the depth direction of the trench 14 (i.e., the thickness direction of the substrate 9) and the principal plane 9a of the substrate 9, respectively. Therefore, the trench 14 reaches the N⁻ type drift layer 11 in the directions X and Y. The gate oxide film 15 is formed on the inner wall of the trench 14. The gate electrode 8 is embedded in the trench 14 through the gate oxide film 7. Multiple gate electrodes 8 are formed in the substrate 9 and aligned in the direction Z.

Then, a gate wiring (not shown) for connecting to the gate electrode 8 is formed on the principal plane 9a of the substrate 9. Further, a source electrode (not shown) for connecting to the N⁺ type source region 13 and the P type channel region 12 is formed on the principal plane 9a. A drain electrode (not shown) for connecting to the N⁺ type substrate 9 as a drain region is formed on the backside surface of the substrate 9.

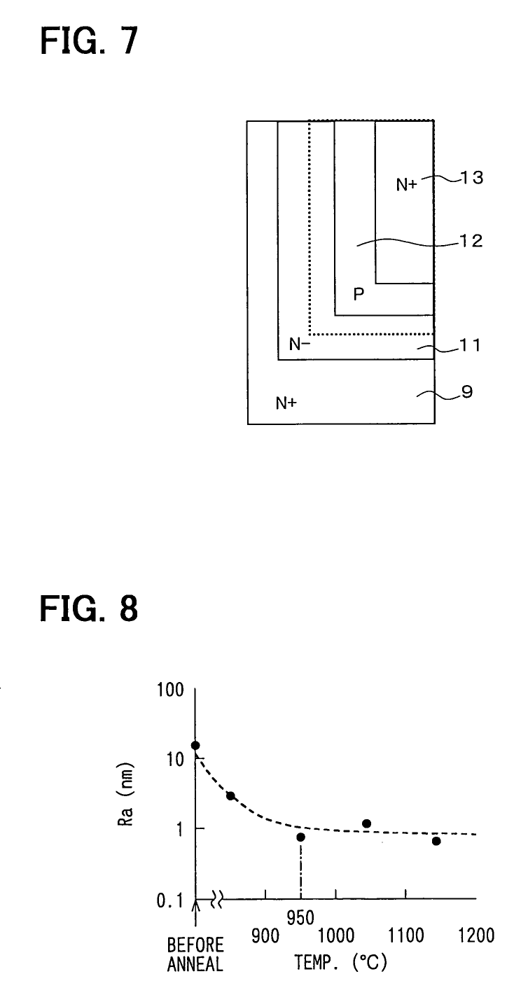

FIG. 7 is a cross sectional view showing the substrate taken along line VIII-VIII in FIG. 6. This drawing corresponds to a cross section of MOSFET taken along with the sidewall of the trench 7. As shown a dotted line in FIG. 7, a trench gate is formed to penetrate the P type channel region 12 from the N⁺ type source region 13. Here, the dotted line shows the inner wall of the trench 14 just after the trench etching process. Further, the N⁺ type source region 13 having high impurity concentration provides a part of the sidewall of the trench 14 just after the trench etching process. In this case, in the annealing process after the trench etching process, in general, the impurity near the inner wall of the trench 14 is easily diffused outwardly. However, in the annealing process, the substrate 9 is annealed in the hydrogen gas having the partial pressure equal to or higher than 20 kPa at a temperature between 950° C. and 1050° C., so that the crystal defects near the trench 14 are recovered without diffusing the impurity in the substrate 9 outwardly and the shape of the trench 14 is suitable for forming the gate oxide film 7.

(Modifications)

In the gate insulation film forming process shown in FIG. 1D, after the gate oxide film 7 is formed by the CVD (i.e., chemical vapor deposition) method, a nitride film can be formed on the gate oxide film 7. Further, a thermal oxidation film is formed on the nitride film so that a multi-layer film having the oxide film/nitride film/oxide film structure (i.e., an ONO film) is formed on the inner wall of the trench 14. In this case, the ONO film works as a gate insulation film, and has excellent dielectric constant. Further, the trench gate has the low density of the crystal defects.

Although the power MOSFET is a vertical type MOSFET, the method for manufacturing the trench gate can be used for a horizontal type MOSFET having a trench gate. Although the MOSFET is the N type MOSFET, the method can be used for a P type MOSFET.

Such changes and modifications are to be understood as being within the scope of the present invention as defined by the appended claims.

What is claimed is:

1. A method for manufacturing a semiconductor device having a trench gate, the method comprising the steps of:
forming a trench in a substrate, the trench having a depth equal to or deeper than 10 μm;
annealing the substrate in a reducing atmosphere; and
forming a gate insulation film on an inner wall of the trench,
wherein the substrate is annealed at a temperature between 950° C. and 1030° C. under a pressure of the reducing atmosphere equal to or higher than 20 kPa in the step of annealing.

2. The method according to claim 1,
wherein the substrate is annealed at a temperature between 950° C. and 1030° C. under a pressure equal to or higher than 30 kPa in the step of annealing.

3. The method according to claim 1,
wherein the substrate is annealed at a temperature between 950° C. and 1030° C. under a pressure equal to or higher than 40 kPa in the step of annealing.

4. The method according to claim 1,
wherein the pressure of the reducing atmosphere is a partial pressure.

5. The method according to claim 1,
wherein the reducing atmosphere is a hydrogen gas atmosphere.

6. The method according to claim 1,
wherein the gate insulation film is an oxide film formed by a CVD method.

7. The method according to claim 1,
wherein the gate insulation film includes an oxide film formed by a CVD method, a nitride film and an oxide film formed by a thermal oxidation method, which are stacked in this order.

8. The method according to claim 1,
wherein the semiconductor device is a vertical type MOSFET or a horizontal type MOSFET.

9. The method according to claim 1,
wherein the substrate is made of silicon, and
wherein the gate insulation film is made of silicon oxides.

10. A method for manufacturing a semiconductor device having a trench gate, the method comprising the steps of:
preparing a semiconductor substrate having a first surface and a second surface opposite to the first surface, the substrate including a source region having a first conductive type, a channel region having a second conductive type, a drift region, and a drain region having the first conductive type,
wherein the drain region extends in a vertical direction of the first surface, and is disposed on the first surface of the substrate,
wherein the drift region is disposed in the drain region, and extends in the vertical direction of the first surface of the substrate,
wherein the channel region is disposed in the drift region, and extends in the vertical direction of the first surface of the substrate, and
wherein the source region is disposed in the channel region, and extends in the vertical direction of the first surface of the substrate;
forming a trench having a depth equal to or deeper than 10 μm, the trench penetrating the channel region from the source region to reach the drift region in one of directions parallel to the first surface of the substrate;
annealing the substrate in a reducing atmosphere;
forming a gate insulation film on an inner wall of the trench; and
forming a gate electrode in the trench through the gate insulation film,
wherein the substrate is annealed at a temperature between 950° C. and 1030° C. under a pressure of the reducing atmosphere equal to or higher than 20 kPa in the step of annealing.

11. The method according to claim 10,
wherein the substrate is annealed at a temperature between 950° C. and 1030° C. under a pressure equal to or higher than 30 kPa in the step of annealing.

12. The method according to claim 10,
wherein the substrate is annealed at a temperature between 950° C. and 1030° C. under a pressure equal to or higher than 40 kPa in the step of annealing.

13. The method according to claim 10,
wherein the pressure of the reducing atmosphere is a partial pressure.

14. The method according to claim 10,
wherein the reducing atmosphere is a hydrogen gas atmosphere.

15. The method according to claim 10,
wherein the gate insulation film is an oxide film formed by a CVD method.

16. The method according to claim 10,
wherein the gate insulation film includes an oxide film formed by a CVD method, a nitride film and an oxide film formed by a thermal oxidation method, which are stacked in this order.

17. The method according to claim 10,
wherein the semiconductor device is a vertical type MOSFET or a horizontal type MOSFET.

18. The method according to claim 10,
wherein the substrate is made of silicon, and
wherein the gate insulation film is made of silicon oxides.
